(19) United States
(12) Patent Application Publication
(10) Pub. No.: US 2007/0293026 A1
(43) Pub. Date: Dec. 20, 2007

(54) METHOD OF MANUFACTURING SEMICONDUCTOR DEVICE

(75) Inventors: Min Sik Jang, Icheon-si (KR); Noh Yeal Kwak, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/616,023

(22) Filed: Dec. 26, 2006

(30) Foreign Application Priority Data
Jun. 16, 2006 (KR) 2006-54420
Sep. 29, 2006 (KR) 2006-96002

(51) Int. Cl. H01L 21/425

(52) U.S. Cl. 438/514; 438/550; 257/E27.147; 257/E21.497

(57) ABSTRACT

A method of manufacturing a semiconductor device includes the step of performing an ion implantation process for implanting an impurity ion into a semiconductor substrate, and performing annealing in a state where temperature of respective portions of an annealing chamber are set differently in order to activate the impurity ion.

### BACKGROUND OF THE INVENTION

The present invention relates to semiconductor devices, and more particularly to a method of manufacturing a semiconductor device, which can reduce the difference in the threshold voltage of elements formed on the same wafer.

As devices shrink, the level of integration of junctions gradually increases. In order to prohibit the formation of Transient Enhanced Diffusion (TED) junctions due to thermal budget a subsequent high temperature annealing process is performed by Rapid Thermal Process (RTP).

In the high temperature annealing process, abnormal diffusion deeper into the junction due to TED can be prohibited, but the pattern effect incurred by an increased pattern number cannot be prevented. In the high temperature RTP, the temperature is controlled by measuring the temperature at a specific point using a pyro, thermo couple or the like. The pattern effect is caused by changing reflectivity in the wafer, which causes the temperature to vary throughout the wafer as you move from areas with high pattern density to areas that have no patterns.

As the production of electronics becomes diversified, wafer size is gradually increased. The probability that the characteristics of elements formed on the wafer will vary with the increased area becomes high. Furthermore, the difference in the characteristics between the center region and the edge region of the wafer causes a difference in the threshold voltage, resulting in decreased yield.

FIG. 1 is a graph illustrating the variation in the threshold voltage of transistors formed in a single wafer.

From FIG. 1, it can be seen that there is a difference in the threshold voltage of 100 mV or more between transistors formed in a single wafer due to the pattern effect and other processes. In particular, it can be seen that transistors formed in the center region of the wafer has a low threshold voltage compared with transistors formed in other regions.

One of the reasons why the threshold voltage differs between the elements formed on the same wafer is that the diffusion of the junction region differs due to a temperature gradient at the time of the annealing process. For example, after ions for forming a source/drain junction region is implanted, an annealing process is performed in order to diffuse the source/drain junction region. This process is very important because it diffuses the junction region through annealing to smooth the flow of electrons.

As described above, the diffusion step of the junction region has a direct influence on the level of the threshold voltage. In particular, the diffusion step greatly differs depending on the annealing temperature. However, as a wafer having a wide area is used, a temperature gradient is formed by an annealing apparatus. Thus, there occurs a difference in the threshold voltage between elements on the same wafer.

### BRIEF SUMMARY OF THE INVENTION

An embodiment of the present invention is directed to a method of manufacturing a semiconductor device, which can improve threshold voltage distributions of transistors formed on a single wafer by performing an annealing process where temperatures at different locations inside the annealing chamber are set differently.

In one embodiment, a method of manufacturing a semiconductor device includes the steps of performing an ion implantation process for implanting an impurity ion into a semiconductor substrate, and performing annealing in a state where the temperature of respective portions of an annealing chamber are set differently in order to activate the impurity ion.

### BRIEF DESCRIPTION OF THE DRAWINGS

FIG. 1 is a graph illustrating the difference in the threshold voltage of transistors formed at different locations on a single wafer.

FIG. 2 is a graph illustrating the pattern effect of a furnace type RTP and a lamp type RTP.

FIG. 3A is a view illustrating a temperature gradient in the furnace type RTP equipment.

FIG. 3B is a view illustrating the temperature gradient of a wafer at the time of the furnace type RTP.

FIGS. 4A to 4C are cross-sectional views illustrating a method of manufacturing a semiconductor device according to an embodiment of the present invention.

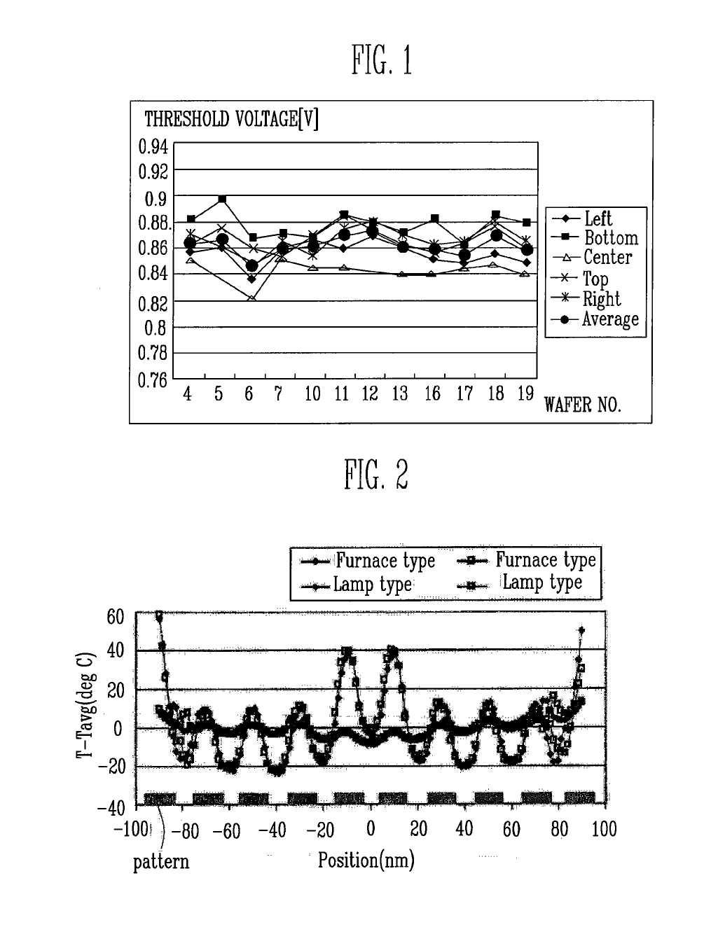

### DESCRIPTION OF SPECIFIC EMBODIMENTS

Specific embodiments according to the present patent will be described with reference to the accompanying drawings.

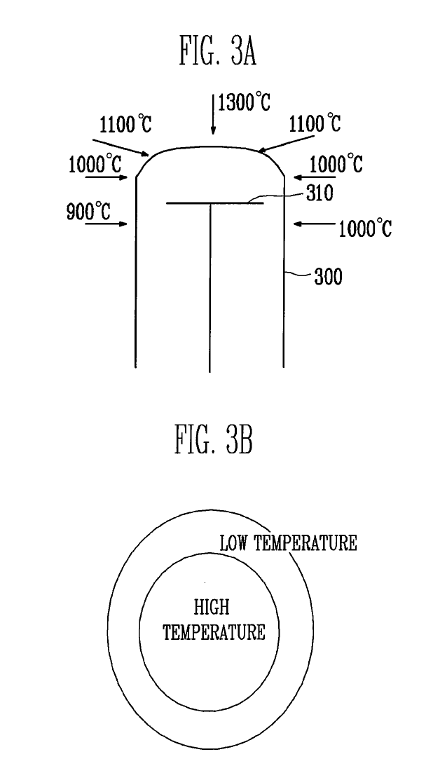

FIG. 2 is a graph illustrating the pattern effect of a furnace type RTP and a lamp type RTP, which shows deviation between a temperature T, measured at the front and rear of a wafer, and an average temperature Tavg on a type basis.

From FIG. 2, it can be seen that when a lamp type RTP is applied, temperature deviation T-Tavg greatly changes depending on the pattern of the chips, and there is a temperature difference of 80 degrees Celsius between a wafer edge region and a center region.

In contrast, when the furnace type RTP is applied, temperature deviation from the chip patterns is small compared with the lamp type RTP, and the difference in temperature between the wafer edge and the center region is less than 20 degrees Celsius.

In the present invention, the furnace type RTP is employed as an annealing process for activating ions implanted into the source and drain junction so as to reduce the difference in the characteristics of transistors, which is incurred by the pattern effect. It is noted that a lamp or line type RTP may be performed instead of the furnace type RTP.

The annealing is performed in a state where the temperature at the top, top corners and sidewalls of the annealing chamber are set differently (a state where the temperature gradient is different) at the time of annealing.

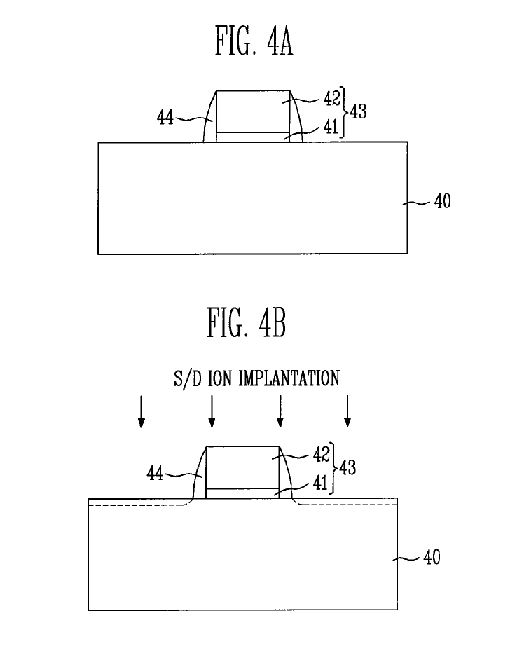

FIG. 3A is a view illustrating a temperature gradient in the furnace type RTP equipment. FIG. 3B is a view illustrating the temperature gradient of a wafer at the time of the furnace type RTP. In FIG. 3A, reference numeral 300 denotes a chamber providing space in which a process is performed, and 310 denotes a boat on which a wafer is loaded.

Referring to FIGS. 3A and 3B, in the furnace type RTP equipment, temperatures at the top, top corners and sidewalls of the chamber 300 are set differently in order to vary the temperature on the wafer.

Thus, if the furnace type RTP having a temperature gradient is performed as the annealing process for activating ions implanted into the source and drain junction, the source and drain junction of transistors formed in the wafer center region diffuses more into the junction than transistors formed on the wafer edge. Consequently, the on current of a transistor in the wafer center region increases, and the threshold voltage rises.

Since the threshold voltage of transistors in the center region rises, which had relatively lower threshold voltage than that of the wafer edge region, it is therefore possible to decrease threshold voltage deviation throughout the wafer.

The temperature gradient is not limited to a temperature on a chamber-region basis, proposed in the present invention, but may be implemented differently depending on the process step. For example, the temperature at the top of the chamber may be set lower than that at the top corners of the chamber, and the temperature at the top corners of the chamber may be set lower than that at the sidewalls of the chamber. In other words, the temperature at the top, top corners and sidewalls of the annealing chamber may be set differently.

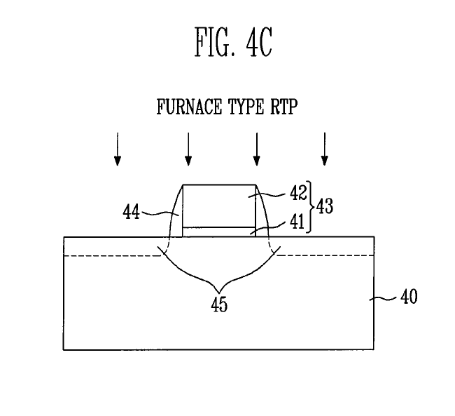

FIGS. 4A to 4C are cross-sectional views illustrating a method of manufacturing a semiconductor device according to an embodiment of the present invention.

Referring to FIG. 4A, an n type dopant is implanted into a semiconductor substrate 40 to form an n well (not shown). In order to control the threshold voltage, ions for controlling the threshold voltage is implanted. The n type dopant may include phosphor (P) ions, and an ion implantation energy of 200 to 1000 KeV and an ion implantation dose of 1E12 to 1E14 ions/cm² may be employed. An ion for controlling the threshold voltage may employ a p type dopant, and an ion implantation energy of 5 to 100 KeV and an ion implantation dose of 1E11 to 1E14 ions/cm² may be employed. In order to prevent channeling of the dopant, the threshold voltage control ion is implanted at a tilt.

A gate oxide layer 41 and a polysilicon layer are sequentially deposited. The polysilicon layer and the gate oxide layer 41 are patterned to form a gate 43 on a specific region. The gate 43 has a structure in which the gate oxide layer 41 and a gate electrode 42 are laminated.

The gate oxide layer 41 is formed by a wet oxidization process in the temperature range of 70 to 800 degrees Celsius. The polysilicon layer is formed using a doped polysilicon layer having a minimum grain size by using SiH₄ or a mixed gas of Si₂H₆ and PH₃ by means of a Low Pressure Chemical Vapor Deposition (LPCVD).

An insulating layer (e.g., a Hot Temperature Oxide (HTO) layer) is formed on the entire surface including the gate 43. A spacer 44 is formed on both sides of the gate 43 by performing a blanket etch. The HTO layer may be formed by LPCVD in the pressure range of 1 to 3 Torr and a temperature range of 650 to 800 degrees Celsius.

Referring to FIG. 4B, an impurity ion for forming the source and drain junction is implanted using the gate electrode 42 and the spacer 43 as masks. The impurity ion may include BF₂ or a mixed gas of B and BF₂.

In the case where BF₂ is used, an ion implantation energy of 1 to 30 KeV and an ion implantation dose of 1E14 to 5E15 ions/cm² are used. In the case where the mixed ion of B and BF₂ is used, BF₂ is implanted with ion implantation energy of 1 to 30 KeV and a dose of 1E14 to 3E15 ions/cm². B is implanted with an ion implantation energy of 1 to 20 KeV and an ion implantation dose of 1E14 to 3E15 ions/cm².

BF₂ has a high atomic weight and is thus effective in forming a shallow junction. The mixed ion of BF₂ and B is effective in prohibiting the occurrence of defects due to an inert dopant.

Referring to FIG. 4C, the furnace type RTP having a temperature gradient is used to diffuse the implanted impurity ion, thus forming a source and drain junction 45. In order to maximize out- gassing of the inert dopant, the furnace type RTP is used with a hydrogen gas atmosphere, and in order to facilitate the process, a nitrogen gas is mixed in with the hydrogen gas.

If the furnace type RTP is used as described above, the pattern effect can be reduced, and deviation in the characteristic of transistors due to the pattern effect can be improved.

Meanwhile, if a p type dopant is implanted as the threshold voltage ion, the threshold voltage of the transistors formed in the wafer center region is low, and the threshold voltage of the transistors formed in the edge region is high. In the furnace type RTP, the temperature gradient is higher in the center region than in the wafer edge region, so that the low threshold voltage of transistors located in the center region can be raised.

Furthermore, the present invention may be applied to an annealing process other than the source/drain junction formation process. As a result, the uniformity of transistor threshold voltages across a single wafer is improved. Accordingly, semiconductor devices can be fabricated stably.

As described above, the present invention has one of more of the following advantages.

The furnace type RTP is used as an annealing process for activating ions implanted into the source and drain junction. Accordingly, the pattern effect can be minimized, and deviation in the characteristic of transistors due to the pattern effect can be improved.

Annealing is performed with temperature gradient. Accordingly, variation in the threshold voltage of the wafer edge region and the wafer center region can be improved, and the uniformity of the threshold voltage can be obtained.

An increase in the uniformity of a single wafer, which becomes serious as the size of the wafer increases, can be solved by simple tuning the annealing method.

Devices can be stably fabricated by actively coping with the short channel effect in which the transistor characteristic is changed a lot by means of a subsequent process of a high temperature

The above embodiments of the present invention are illustrative and various alternatives and modifications are possible in view of the present disclosure and are intended to fall within the spirit and scope of the appended claims.

What is claimed is:

1. A method of manufacturing a semiconductor device, the comprising:
implanting dopants into a semiconductor substrate, the substrate having a first region and a second region; and
activating the dopants implanted in the substrate by subjecting the first and second regions to different activation energies.

2. The method of claim 1, further comprising:
providing the substrate with the dopants implanted therein on a process area of a thermal apparatus to perform the activating step, the thermal apparatus providing the first and second regions with different temperatures.

3. The method of claim 1, further comprising:
providing the substrate with the dopants implanted therein in a thermal apparatus to perform the activating step,
wherein the thermal apparatus includes a chamber wherein the substrate is provided, the chamber having a temperature gradient to provide the first region of the substrate with a first temperature and the second region of the substrate with a second temperature.

4. The method of claim 3, wherein the first region of the substrate is provided proximate to a middle of the substrate and the second region of the substrate is provided proximate to an edge of the substrate.

5. The method of claim 3, wherein the thermal apparatus is a furnace-type apparatus.

6. The method of claim 5, wherein:
a top of the chamber is set to a first chamber temperature, and a sidewall of the chamber is set to a second chamber temperature.

7. The method of claim 6, wherein the first chamber temperature is set higher than the second chamber temperature.

8. The method of claim 2, wherein the first temperature is set higher than the second temperature, and the second temperature is set lower than the third temperature.

9. The method of claim 1, wherein at the time of the annealing process, an annealing chamber has one of a furnace type, a lamp type and a line type.

10. The method of claim 1, wherein the annealing process is performed by a Rapid Thermal Process (RTP).

11. The method of claim 1, wherein the annealing process is performed under a hydrogen gas atmosphere.

12. The method of claim 1, wherein the annealing process is performed under a mixed gas atmosphere of a hydrogen gas and a nitrogen gas.
